(19) United States
(12) Patent Application Publication
(10) Pub. No.: US 2009/0116180 A1
(43) Pub. Date: May 7, 2009

(54) KEYBOARD AND KEYBOARD ASSEMBLING METHOD

(75) Inventor: Jeng-Tai CHEN, Yingge Town (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: DARFON ELECTRONICS CORP., Taoyuan (TW)

(21) Appl. No.: 12/265,818

(22) Filed: Nov. 6, 2008

(30) Foreign Application Priority Data
Nov. 6, 2007 (TW) 096141796
Mar. 11, 2008 (TW) 097108454

(51) Int. Cl. H05K 5/04; H05K 7/18

(52) U.S. Cl. 361/679.08; 29/622

(57) ABSTRACT

The invention discloses a keyboard and keyboard assembling method, and the keyboard is assembled by welding. The keyboard has a first casing, a second casing, and a plurality of key switches. The first casing comprises a plurality of openings; the second casing comprises a plurality of welding portions; and the key switches are partially contained in the openings. The welding portions of the second casing are connected to the first casing by welding to form the keyboard.

### BACKGROUND OF THE INVENTION

1. Field of the Invention

This invention relates to a keyboard and a keyboard assembling method, and more particularly, the invention relates to a keyboard formed by welding and the assembling method thereof.

2. Description of the Prior Art

The input unit of the electronic device (for example, keyboard of computer or PDA) in business conditions is often assembled by fixing the top cover and the base of the input unit by screws. For steadying the input unit, the size of the screws must be larger than a standard value. However, because of the miniaturization trend in the electronic industry recently, the input device also tends to less area and thinner thickness, and the area and the thickness of the screws form a limitation to the miniaturization of the input device.

On the other hand, welding is an important part for an electronic device in the process of the electronic equipment. The purpose for welding is jointing a metal to other object, and the method thereof is melting the metal by heating for jointing. Recently, high power laser welding technique is extensively used in many fields, such as automobile industry, articles and instruments for medical use, electronic device, and other field requiring precise process.

Laser welding has many advantages, such as: the welding could be performed at the place where the laser could reach so as to avoid the influence of the sharps of the work pieces; the energy of the laser could be focused in a tiny area so as to fit high precision welding; the working time is short and the properties of the work pieces would not be changed, and it is very important in welding for different materials; and, the laser welding could be performed in various vapor conditions, magnetic fields, or electric fields. Because of the above-mentioned advantages, the laser welding is fit to precise industry such as national defense, space flight, automobile, and electronic industry.

Therefore, the invention provides a keyboard fabricated by welding, and more particularly, by laser welding for fit the trend of miniaturization.

However, laser welding could not avoid material deformation due to residual stress generated by the heating and welding on the workpieces. Although the residual stress of laser welding has been smaller than that of traditional welding, the deformation caused by the residual stress of laser welding still brings significant influence to the precision required by the workpieces because the workpieces in laser welding process often have smaller area, volume, or thickness. The above-mentioned problem further decreases quality of the products.

Therefore, the invention further provides a method for assisting in welding a keyboard to solve the above-mentioned problem.

### SUMMARY OF THE INVENTION

A scope of the invention is to provide a keyboard assembled by welding and the assembling method thereof.

According to an embodiment, the keyboard of the invention comprises a first casing, a second casing, and a plurality of key switches, wherein the first casing comprises a plurality of openings; the second casing comprises a plurality of welding portions. The key switches are disposed on the second casing and partially contained in the openings of the first casing. In this embodiment, the welding portions of the second casing are connected to the first casing by welding. Besides, the welding portions of the second casing have protruding structures formed by stamping the second casing, and the protruding structures can contact the first casing for assisting in welding.

In this embodiment, the first casing and the second casing could be clipped firstly in the assembling method of the keyboard to make the welding portions of the second casing to contact the first casing. And then, the welding portions of the second casing could be connected to the first casing by welding to form the casing construction of the keyboard.

Another scope of the invention is to provide a keyboard assembling method for assisting in assembling a casing construction of a keyboard by welding, and more particularly, the keyboard assembling method can avoid the critical deformation of workpieces after welding so as to improve the quality.

According to an embodiment, the keyboard assembling method of the invention comprises the following steps: firstly, a first thermal control device providing a first casing with a first temperature and keeping the first temperature, and a second thermal control device providing a second casing with a second temperature and keeping the second temperature, wherein the first temperature is lower than the second temperature; and then, the first thermal control device and the second thermal control device working in coordination to clip the first casing and the second casing, so that the first casing staying close to the second casing; finally, welding the first casing and the second casing to form the casing construction.

In this embodiment, the first casing and the second casing respectively have a plurality of first welding points and a plurality of second welding points. When the first casing stays close to the second casing, the first welding points contact the corresponding second welding points respectively. Besides, the first thermal control device further comprises a first main body and a first thermal controller for controlling and keeping the temperature of the first main body, and the first thermal controller can make the first main body to substantially keep the first temperature; the second thermal control device further comprises a second main body and a second thermal controller for controlling and keeping the temperature of the second main body, and the second thermal controller can make the second main body to substantially keep the second temperature.

Wherein, the first main body of the first thermal control device directly contacts the first casing, and because the first casing is made of a thermal conductive material with fine thermal conductivity, it can substantially keep the first temperature. Besides, the second main body of the second thermal control device directly contacts the second casing, and because the second casing is made of a thermal conductive material with fine thermal conductivity, it can substantially keep the second temperature.

In this embodiment, the first thermal control device and/or the second thermal control device can further comprise a plurality of welding holes. The first welding points of the first casing and the second casing can receive welding through the welding holes respectively.

The advantage and spirit of the invention may be understood by the following recitations together with the appended drawings.

### BRIEF DESCRIPTION OF THE APPENDED DRAWINGS

FIG. 1 is a section diagram illustrating the keyboard according to an embodiment of the invention.

FIG. 2 is a flow chart illustrating the keyboard assembling method according to an embodiment of the invention.

FIG. 3 is a section diagram illustrating that the first thermal control device and the second thermal control device in FIG. 2 work in cooperation to clip the first casing and the second casing.

FIG. 4 is a schematic diagram illustrating that the keyboard is assembled by welding according to an embodiment of the invention.

### DETAILED DESCRIPTION OF THE INVENTION

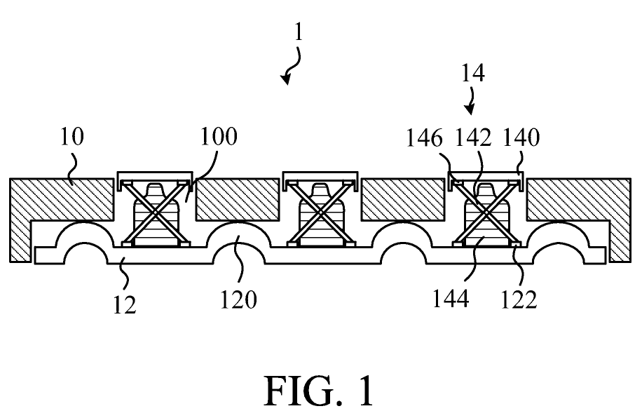

Please refer to FIG. 1. FIG. 1 is a section diagram illustrating the keyboard 1 according to an embodiment of the invention. As shown in FIG. 1, the keyboard 1 comprises the first casing 10, the second casing 12, and a plurality of key switches 14. Wherein, the first casing 10 further comprises a plurality of openings 100, and the second casing 10 comprises a plurality of welding portions 120. The key switches 14 are respectively disposed on the second casing 12 and partially contained in the openings 100.

In this embodiment, the welding portions 120 protrudes from the second casing 12 and contacts the first casing 10, and the welding portions 120 could be connected to the first casing 10 by welding. In other words, the first casing 10 and the second casing 12 could be connected by welding. Practically, the protruding structure of the welding portions 120 could be formed on a surface of the second casing 12 by stamping the opposite surface of the second casing 12.

Practically, the assembling method of the keyboard 1 has the following step: firstly clipping the first casing 10 and the second casing 12 to cause the welding portions 120 of the second casing 12 to contact the first casing 10; and welding the first casing 10 and the welding portions 120 to make the first casing 10 and the second casing 12 to integrate to form the casing construction of the keyboard 1.

Besides, the key switches 14 further comprise the keycaps 140, the supporting structures 142, and the elastic members 144. In this embodiment, the keycaps 140 respectively have a first connecting part 146, and the second casing 12 has second connecting parts 122. The supporting structures 142 are scissor supporting-structures, however, the supporting structures could be other structures capable of limiting the movement of the keycaps, and it is not limited to this embodiment. Through the first connecting parts 146 and the second connecting parts 122, the supporting structures 142 can connect the keycaps 140 and the second casing 12 to make the key switches 14 to link on the keyboard 1. Furthermore, the elastic members 144 are respectively disposed between the keycaps 140 and the second casing 12, and when the key switches 14 are pressed, the elastic members 144 would deform to provide elastic forces to assist the keycaps 140 back to the original positions.

Practically, the key switches 14 can comprise switch units (not shown in the figure), and the switch units would be triggered and then transmit signals when the key switches 14 are pressed. Besides, a thin film circuit board (not shown in the figure) could be disposed between the first casing 10 and the second casing 12. The thin film circuit board could be electrically connected to the switch units and receive the signals transmitted by the switch units to judge if the key switches 14 are press.

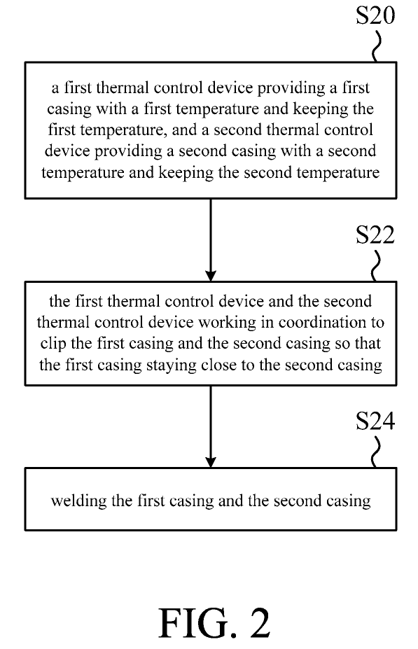

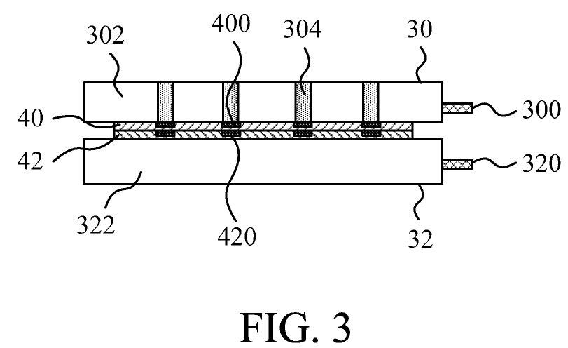

Please refer to FIG. 2 and FIG. 3 together. FIG. 2 is a flow chart illustrating the keyboard assembling method according to an embodiment of the invention; FIG. 3 is a section diagram illustrating that the first thermal control device and the second thermal control device in FIG. 2 work in cooperation to clip the first casing and the second casing. As shown in FIG. 2, the keyboard assembling method in this embodiment is used for assisting in welding the first casing and the second casing of the keyboard, and the method comprises the following steps: firstly, in step S20, a first thermal control device providing a first casing with a first temperature and keeping the first temperature, and a second thermal control device providing a second casing with a second temperature and keeping the second temperature; and then, in step S22, the first thermal control device and the second thermal control device working in coordination to clip the first casing and the second casing, so that the first casing staying close to the second casing; finally, in step S24, welding the first casing and the second casing.

It should be noted that step S22 is executed after step S20 in this embodiment, however, in practice, step S22 could be executed before step S20. In other words, the first thermal control device and the second thermal control device clip the first casing and the second casing firstly, and then respectively control the temperature of the first casing and the second casing.

As shown in FIG. 3, the first thermal control device 30 further comprises the first thermal controller 300 and the first main body 302, and the second thermal control device 32 further comprises a second thermal controller 320 and the second main body 322. The first thermal controller 300 provides the first main body 302 with the first temperature and keeps the first temperature, and the second thermal controller 320 provides the second main body 322 with the second temperature and keeps the second temperature. Practically, the first temperature could be lower than the second temperature, for example, the first temperature could be 20° C. and the second temperature could be 80° C. It should be noted that the shapes and positions of the first thermal control device, the second thermal control device, the first main body, the second main body, the first thermal controller, and the second thermal controller could be variable according to the requirement of the user in practice.

In this embodiment, the first casing 40 comprises a plurality of first welding points 400, and the second casing 42 comprises a plurality of second welding points 420 corresponding to the first welding points 400 respectively. The first thermal control device 30 and the second thermal control device 32 work in cooperation to clip the first casing 40 and the second casing 42, so that the first casing 40 stays close to the second casing 42, as shown in FIG. 3. Besides, when the first casing 40 stays close to the second casing 42, each of the first welding points 400 stays close to the corresponding second welding point 420 too.

In this embodiment, the first main body 302, the second main body 322, the first casing 40, and the second casing 42 could be made of thermal conductive materials with fine thermal conductivity. It should be noted that the thermal conductive materials are not required to be the same, for example, the first casing 40 and the second casing 42 could be made of aluminum, and the first main body 302 and the second main body 322 could be made of another thermal conductive material except aluminum. Because the first main body 302, the second main body 322, the first casing 40, and the second casing 42 are provided with fine thermal conductivity, the first casing 40 can receive and substantially keep the first temperature from the first main body 302, and the second casing 42 can receive and substantially keep the second temperature form the second main body 322.

Besides, the first main body 302 of the first thermal control device 30 can comprise a plurality of welding holes 304. The welding holes 304 are respectively corresponding to the first welding points 400 and the second welding points 420. When the first thermal control device 30 and the second thermal control device 32 clip the first casing 40 and the second casing 42, each of the first welding points 400 and the corresponding second welding point 420 can receive welding through the welding holes 304. Practically, especially in precise welding process, the laser welding could be used to weld the first welding points 400 and the second welding points 420 through the welding holes 304.

According to another embodiment, the difference between this embodiment and the last embodiment is that the second main body of the second thermal control device but not the first main body of the first thermal control device comprises a plurality of welding holes, wherein the welding holes are respectively corresponding to the first welding points and the second welding points. Accordingly, in the condition that the first casing substantially keeps the first temperature and the second casing substantially keeps the second temperature, the first welding points and the corresponding second welding points can receive welding through the welding holes of the second main body.

According to another embodiment, the difference between this embodiment and the last embodiment is that the first main body of the first thermal control device comprises a plurality of first welding holes, and the second main body of the second thermal control device comprises a plurality of second welding holes, wherein the first welding holes and the second welding holes are respectively corresponding to the first welding points and the second welding points. Accordingly, in the condition that the first casing substantially keeps the first temperature and the second casing substantially keeps the second temperature, the first welding points and the corresponding second welding points can receive welding selectively through the first welding holes of the first main body and/or the second welding holes of the second main body.

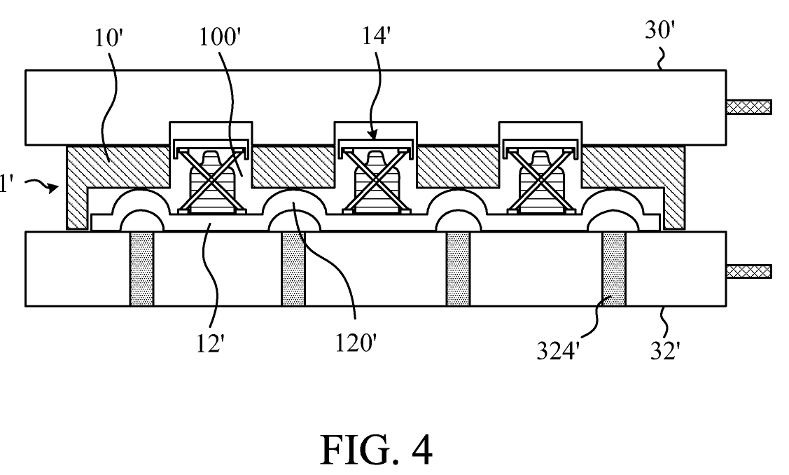

Practically, the first casing and the second casing in the above-mentioned embodiments could be the top cover and base of the keyboard. Please refer to FIG. 1 and FIG. 4 together. FIG. 4 is a schematic diagram illustrating that the keyboard 1′ is assembled by welding according to an embodiment of the invention. As shown in FIG. 4, the top cover 10′ of the keyboard 1′ is the first casing 10 in FIG. 1, and the base 12′ of the keyboard 1′ is the second casing 12 in FIG. 1. In this embodiment, the first thermal control device 30′ and the second thermal control device 32′ work in cooperation to clip the top cover 10′ and the base 12′, and the top cover 10′ receives and substantially keeps the first temperature from the first thermal control device 30′ and the base receives and substantially keeps the second from the second thermal control device 32′.

Similarly, in this embodiment, the top cover 10′ further comprises a plurality of openings 100′, and the base 12′ further comprises a plurality of welding portions 120′. The key switches 14′ are disposed on the base 12′ and contained in the openings 100′. The welding portions 120′ have protruding structures, formed by stamping, for contacting the top cover 10′.

Besides, the second thermal control device 32′ comprises welding holes 324′ respectively corresponding to the welding portions 120′. When the first thermal control device 30′ and the second thermal control device 32′ substantially keep the first temperature and the second temperature of the top cover 10′ and the base 12′, the welding portions 120′ can receive welding (such as laser welding) through welding holes 324′. Therefore, through the first thermal control device 30′ and the second thermal control device 32′, the keyboard 1′ could be assembled by welding and the original shapes of the top cover 10′ and the base 12′ could be substantially maintained after welding.

Compared to the prior art, the keyboard and the keyboard assembling method of the invention provide a welding method for welding the top cover and the base of the keyboard. During welding, the top cover and the base are controlled to keep different temperatures respectively so as to generate a temperature difference. After welding, the top cover and the base can substantially maintain their original shapes so as to decrease the deformation caused by the residual stress generated by welding, so that the assembling of the invention can avoid the critical deformation influencing the quality of the keyboard.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A keyboard, comprising:
a first casing, comprising a plurality of openings;
a second casing, having a plurality of welding portions; and
a plurality of key switches, disposed on the second casing, the key switches are partially contained in the openings;
wherein, the welding portions of the second casing are connected to the first casing by welding.

2. The keyboard of claim 1, wherein each of the welding portions of the second casing has a protruding structure to contact the first casing.

3. The keyboard of claim 2, wherein the protruding structure is formed by stamping.

4. The keyboard of claim 1, further comprising a thin film circuit board disposed between the first casing and the second casing.

5. The keyboard of claim 1, wherein the key switches comprise:
a plurality of keycaps; and
a plurality of supporting structures, contained in the openings and respectively connecting the keycaps and the second casing.

6. The keyboard of claim 5, wherein the supporting structures are scissor supporting-structures, and the second casing and the keycaps respectively have a connecting part by which the scissor supporting-structures connect the second casing and the keycaps.

7. The keyboard of claim 6, further comprising a plurality of elastic members disposed between the keycaps and the second casing.

8. A keyboard assembling method, for assisting in assembling a casing construction of a keyboard, the keyboard assembling method comprising the following steps:
(a1) a first thermal control device providing a first casing with a first temperature and keeping the first temperature, and a second thermal control device providing a second casing with a second temperature and keeping the second temperature, wherein the first temperature is lower than the second temperature;
(a2) the first thermal control device and the second thermal control device working in coordination to clip the first casing and the second casing, so that the first casing staying close to the second casing; and
(a3) welding the first casing and the second casing to form the casing construction.

9. The keyboard assembling method of claim 8, wherein the first casing further comprises a plurality of first welding points, and the second casing comprises a plurality of second welding points respectively corresponding to the first welding points, when the first casing stays close to the second casing, the first welding points contact the corresponding second welding points respectively.

10. The keyboard assembling method of claim 9, wherein the first thermal control device and/or the second thermal control device further comprise a plurality of welding holes, each of the first welding points and the corresponding second welding points receives welding through the welding holes respectively.

11. The keyboard assembling method of claim 8, wherein the first thermal control device further comprises:
a first main body, made of a thermal conductive material with fine thermal conductivity; and
a first thermal controller, for controlling the temperature of the first main body to cause the first main body to keep the first temperature.

12. The keyboard assembling method of claim 8, wherein the second thermal control device further comprises:
a second main body, made of a thermal conductive material with fine thermal conductivity; and
a second thermal controller, for controlling the temperature of the second main body to cause the second main body to keep the second temperature.

13. The keyboard assembling method of claim 8, wherein the first casing and the second casing are made of a thermal conductive material with fine thermal conductivity.

14. The keyboard assembling method of claim 13, wherein the thermal conductive material is aluminum.

15. The keyboard assembling method of claim 8, wherein the first casing and the second casing are the top cover and the base of the keyboard.

16. The keyboard assembling method of claim 8, wherein the first temperature comprises 20° C.

17. The keyboard assembling method of claim 8, wherein the second temperature comprises 80° C.

18. The keyboard assembling method of claim 8, wherein the first casing and the second casing are welded by laser.

19. A keyboard assembling method, for assembling a casing construction of a keyboard, the keyboard comprising a first casing, a second casing, and a plurality of key switches, the first casing comprising a plurality of openings, the second casing having a plurality of welding portions, the key switches being disposed on the second casing and contained in the openings, the keyboard assembling method comprising the following steps:
(a1) clipping the first casing and the second casing to cause the first casing to stay close to the second casing; and
(a2) welding the first casing and the second casing to form the casing construction.

20. The keyboard assembling method of claim 19, wherein the first casing further comprises a plurality of first welding points, and the second casing further comprises a plurality of second welding points respectively corresponding to the first welding points, when the first casing stays close to the second casing, the first welding points contact the corresponding second welding points respectively.

21. The keyboard assembling method of claim 19, wherein the first casing and the second casing are made of a thermal conductive material with fine thermal conductivity.

22. The keyboard assembling method of claim 21, wherein the thermal conductive material is aluminum.

23. The keyboard assembling method of claim 19, wherein the first casing and the second casing are the top cover and the base of the keyboard.

24. The keyboard assembling method of claim 19, wherein the first casing and the second casing are welded by laser.
